(19) United States
(12) Patent Application Publication
(10) Pub. No.: US 2026/0360039 A1
(43) Pub. Date: Nov. 12, 2026

(54) COMPRESSED SENSING USING SPARSITY ENHANCEMENT ACROSS SINGLE-SHOT DATA SETS

(71) Applicant: Siemens Healthineers AG, Forchheim (DE)

(72) Inventor: Wolfgang Rehwald, Chapel Hill, NC (US)

(21) Appl. No.: 19/465,602

(22) Filed: Jan. 30, 2026

Related U.S. Application Data
(60) Provisional application No. 63/803,060, filed on May 9, 2025.

(51) Int. Cl. G06T 11/60; G01R 33/48; G01R 33/56; G06T 12/20

(52) U.S. Cl. CPC G06T 11/60; G01R 33/4818; G01R 33/5608; G06T 12/20

(57) ABSTRACT

A system and method comprises acquisition of k-space data sets, each of the k-space data sets comprising a different incoherent variable-density under-sampled combination of k-space phase encoding lines, reconstruction of a first image from each of the k-space data sets, selection of a plurality of the reconstructed first images, determination of a plurality of k-space data sets from which the selected plurality of the first images were reconstructed, the plurality of k-space data sets being a proper subset of the k-space data sets, joint reconstruction of a second image from each of the plurality of k-space data sets, and generation of a composite image based on the second images.

### CROSS-REFERENCE TO RELATED APPLICATIONS

This application claims priority to U.S. Provisional Patent Application No. 63/803,060, filed May 9, 2025, the disclosure of which is incorporated herein by reference for all purposes.

### BACKGROUND

A Magnetic Resonance (MR) scanner uses magnetic fields and timed sequences of radio-frequency (RF) pulses to generate anatomical images. MR imaging is useful in scenarios requiring high contrast between different soft tissue types.

MR imaging consists of acquiring k-space data and calculating an image from the k-space data using a two-dimensional Fast Fourier Transform (FFT). Different regions of k-space represent different image properties. For example, the center region of k-space contains image brightness and contrast information, and the edges of k-space contain image sharpness and detail information. A low-resolution image may therefore be calculated using only k-space data from the center region of k-space. A high-resolution image typically requires k-space data from all of k-space.

In segmented MR imaging, an image is reconstructed from k-space data acquired in multiple shots. Each shot acquires a different portion of k-space, for example m lines of an n-line k-space. Typically, each shot is taken with precise temporal resolution (i.e., in the same cardiac phase but in a different heartbeat). Acquisition of all k-space lines therefore occurs over n/m heartbeats.

Late Gadolinium Enhancement (LGE) includes injection of a T1-shortening Gadolinium-based contrast agent into a patient followed by execution of an inversion recovery (IR)-prepared pulse sequence. When used for cardiac imaging, for example, the LGE sequence produces T1-weighted images in which viable (i.e., healthy, living) myocardium appears dark and infarcted (i.e., dead) myocardium appears bright. The amount of data (i.e., number of k-space lines) needed to create an LGE image with high spatial and temporal resolution is too large to be acquired in a single shot. Therefore, the data is acquired in segments over multiple heartbeats while the patient holds their breath.

These breath-held, high-spatial resolution segmented LGE images are susceptible to ghosting artifacts. Ghosting artifacts are fake, periodic replications of moving structures such as the myocardial wall and the interface between chest fat and surrounding air. Ghosting artifacts can be caused by small motions resulting from imperfect breath holding, arrhythmia, or poor ECG-triggering.

Ghosting artifacts are naturally absent from single-shot images due to the relative absence of motion during their short acquisition time. However, even at similar spatial resolutions, a single-shot image exhibits a lower signal-to-noise ratio (SNR), poorer temporal resolution, and reduced T1-contrast as compared to an image resulting from a segmented acquisition.

Previous systems to improve single-shot imaging include a Compressed Sensing (CS)-accelerated multiple single-shot IR-prepared pulse sequence and corresponding reconstruction. Images reconstructed from each single shot exhibit artifacts which are unique to each image. The images are combined (e.g., averaged) to generate an image exhibiting substantially reduced artifacts.

Surprisingly, free breathing during the multiple CS single-shot acquisitions significantly reduces the sparsity of the acquired data. Since reduced sparsity hinders the complete removal of fold-in artifacts, CS images reconstructed from free breathing data are of unexpectedly poor quality. Systems are desired to efficiently generate high-quality images using single-shot k-space data acquired during free breathing.

### BRIEF DESCRIPTION OF THE DRAWINGS

FIG. 1 illustrates acquisition of multiple different incoherent distributions of k-space data and generation of an enhanced-sparsity image from a subset thereof according to some embodiments.

FIG. 2 is a flow diagram of a process to enhance the sparsity of multiple different incoherent distributions of k-space data and generate an image therefrom according to some embodiments.

FIG. 3 illustrates different incoherent distributions of k-space data acquired in respective single shots according to some embodiments.

FIG. 4 illustrates a pulse sequence to acquire different incoherent distributions of k-space data in respective single shots according to some embodiments.

FIG. 5 illustrates single-shot images acquired using the FIG. 4 pulse sequence according to some embodiments.

FIG. 6 illustrates similar ones of the FIG. 5 images according to some embodiments.

FIG. 7 illustrates a combined image generated from the FIG. 6 images according to some embodiments.

FIG. 8 is a block diagram of an example MR system for use in some embodiments.

### DETAILED DESCRIPTION

The following description is provided to enable any person in the art to make and use the described embodiments. Various modifications will remain apparent to those in the art.

The present inventor has discovered that the reduced sparsity of a free breathing-acquired series of k-space data sets as compared to a breath hold-acquired series can be explained by at least two phenomena. First, during respiratory motion, a morphological slice conditioned by one acquisition will shift out of the slice position of the next acquisition. The prescribed slice will remain the same, but the tissue will move due to the respiration, leading to the excitation of different morphological slices. During the end-expiratory periods of respiration when motion does not occur between acquisitions, successive acquisitions will excite the same morphological slice. Therefore, the image content representing the morphology in the resulting series of images will vary quasi-randomly and reduce the series sparsity.

Second, a slice undergoes the same dynamic process between and during each acquisition if the slice is imaged multiple times during a breath hold. The magnetization of the slice will therefore be in a steady state such that the magnetization and the resulting image intensities will be similar between acquisitions. The steady state is determined by the timing between the IR pulse and the data readout and the spacing, number, and flip angle of the readout pulses. Due to the similar magnetization and the resulting image intensities, sparsity is high during breath holding. During free breathing, however, no steady state is created by the readout pulses since mostly different morphological slices are excited by each acquisition, resulting in reduced sparsity.

The inventive system addresses the above by determining the similarity of all k-space data sets acquired free breathing to one another and identifying those data sets which meet a similarity standard. The sparsity of the identified data sets is greater than the sparsity of the originally-acquired data sets. Accordingly, reconstructing only the identified data sets results in artifact-reduced images.

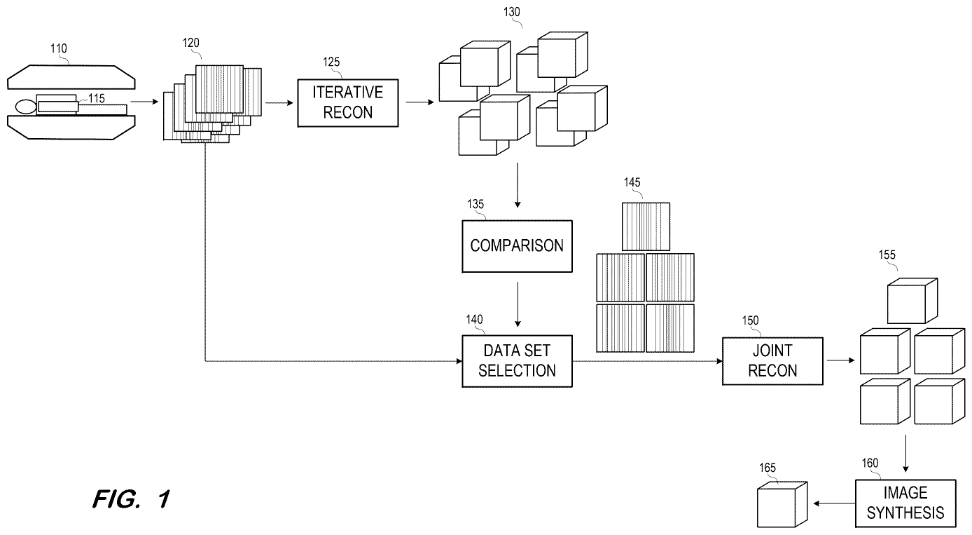

FIG. 1 illustrates acquisition of multiple different incoherent distributions of k-space data and generation of an image from an enhanced-sparsity subset thereof according to some embodiments. The illustrated components of FIG. 1 may be implemented using any combinations of hardware and/or software that are or become known. One or more components may be implemented using the same combination of hardware and/or software (e.g., a desktop computer, a physical server, a virtual server). The processes illustrated in FIG. 1 may be executed temporally and/or physically distant from one another.

MR scanner 110 is used to acquire k-space data representing patient 115. As is known in the art, acquisition of the k-space data may be preceded by injecting a contrast agent into patient 115. K-space data is acquired by executing one or more pulse sequences as is known in the art. The pulse sequences may be designed to acquire particular lines of k-space.

According to Cartesian k-space sampling, k-space is defined by a phase encoding (PE) direction and a perpendicular frequency encoding (FE) direction. K-space lines are disposed on an evenly-spaced grid in which all neighboring lines are the same distance from one another in the PE direction. A sampling “distribution” describes a subset of PE lines in k-space that are acquired by a given pulse sequence. Each readout within a pulse sequence acquires one PE line of raw data and multiple readouts may be performed in one shot. Accordingly, each shot may acquire a desired subset of PE lines, also referred to herein as a set of k-space data.

To accelerate acquisition, some techniques such as GRAPPA or SENSE acquire every n-th (e.g., every other) PE line and calculate the non-acquired lines based on the acquired lines and the coil sensitivities of multiple receiver coil elements. The lines acquired by these techniques are distributed according to a regular, periodic pattern. In CS, each shot acquires a set of k-space data corresponding to an incoherent (e.g., pseudo-random), variable-density distribution of PE lines. Since most of the k-space energy is near the center, the distribution usually samples the central PE lines of k-space more densely than the periphery.

FIG. 1 illustrates the acquisition of k-space data sets 120. Each of data sets 120 corresponds to a respective distribution of a plurality of k-space lines and is acquired in a single shot. Each distribution is CS-compatible (i.e., pseudo-random, variable-density and undersampled) as is known in the art. Moreover, each distribution differs from each other distribution.

Iterative construction component 125 generates images 130 based on k-space data sets 120. Although images 130 are depicted as three-dimensional images, embodiments also encompass two-dimensional image reconstruction. Iterative construction component 125 may perform CS reconstruction to maximize data consistency and transform sparsity as is known in the art. Each of images 130 may be reconstructed based on a single one of data sets 120. Advantageously, each of images 130 may be jointly reconstructed based on data of all of data sets 120 and relying on temporal sparsity among all of data sets 120. In the latter case, temporal sparsity may be achieved by designing a pulse sequence such that each of k-space data sets 120 is acquired from the same region of interest during the same phase of motion.

Comparison component 135 compares images 130 to one another to identify a set of most-similar images therefrom. Comparison component 135 may perform the image comparison and image identification in any suitable manner that is or becomes known. For example, comparison component 135 may identify the respiratory position depicted in each of images 130 and identify a set of images 130 which depict the most similar respiratory positions. The most similar respiratory positions may be determined via image analysis and/or correlating images 130 with an external respiratory motion signal.

Image analysis by comparison component 130 may consist of subtracting images 130 from one another to determine a similarity value. For example, the values of the pixels of images 130 are complex numbers. Subtracting a complex-valued image from another complex-valued image results in a complex-valued difference image. The magnitude of each pixel value of the difference image is calculated to determine a magnitude difference image. The magnitudes of the pixels are summed to generate a cumulative sum, which is a metric representing the similarity of the two images. The smaller the cumulative sum, the more similar are the two images.

According to some embodiments, two images 130 are converted to magnitude images and a difference image is calculated therefrom. The value of each pixel of the difference image is a positive or a negative real number. The positive numbers are summed and the negative numbers are separately summed. The sum having the smaller absolute value is the metric of similarity. The foregoing approach is more robust towards ghosting artifacts which may cause actually-similar images (e.g., depicting similar cardiac positions) to be not correctly identified as similar.

In yet another embodiment, comparison component 135 determines displacement maps between each pair of images 130. The absolute values of the x-components and y-components of each displacement vector of a displacement map may be summed to determine a similarity metric, in which lower sums indicate greater similarity. A different similarity metric may be obtained by adding up the lengths of the displacement vectors (i.e., where length=sqrt[(x_deformation)²+(y_deformation)²]) across all pixels and dividing by the number of pixels. A displacement maps may consider pixels within the whole field of view or only those pixels within a region of interest.

In some embodiments, comparison component 135 considers only pixels of images 130 located in a predefined region of interest. The predefined region of interest may be a region which is more susceptible to motion, such as the heart region. The predefined region of interest may be selected by an operator viewing images 130, by automated image segmentation algorithms, or any combination thereof. For the metric to be independent of the size of the region of interest, it can be divided by the number of pixels within the region. The images identified by component 135 may consist of a predefined number of most-similar images, all images which satisfy a given similarity threshold, all images which satisfy a given similarity threshold up to a maximum number of images, etc.

Data set selection component 140 retrieves k-space data sets of data sets 120 which from which the similar images of images 130 were reconstructed. Accordingly, data sets 120 remain stored in a buffer or other memory even after iterative reconstruction into images 130. Data selection component 140 may receive an indication of the identified similar images of images 130 from component 135. Although component comparison component 135 has been described as identifying similar images, embodiments may alternatively identify dissimilar images of images 130 and pass identifiers of the non-dissimilar images of images 130 to data set selection component 140. In other embodiments, component 135 passes identifiers of dissimilar images of images 130 to component 140 and component 140 retrieves all data sets of data sets 120 other than those from which the dissimilar images of images 130 were reconstructed.

Data set selection component 135 passes retrieved k-space data sets 145 to joint reconstruction component 150. K-space data sets 145 comprise a proper subset of data sets 120, i.e., the number of data sets 145 is less than the number of k-space data sets 120. Joint reconstruction component 150 apples an iterative joint reconstruction algorithm to data sets 145 to generate images 155. Each of images 155 corresponds to, i.e., was reconstructed from, a respective one of k-space data sets 145.

As is known in the art, CS reconstruction methods reconstruct images from undersampled data by imposing sparsity constraints in a transform domain or by enforcing total variation or similar regularity constraints. Conventional CS methods operate on each image independently, treating the reconstruction of each image as a separate optimization problem. Independent reconstruction fails to exploit the substantial inter-image correlations present in many multi-image acquisition scenarios. Joint image reconstruction further exploits these correlations among multiple images to improve reconstruction quality. For example, images 155 are reconstructed concurrently from their respective data sets 145 by enforcing, in addition to the above-mentioned constraints, a shared structural prior that couples the reconstruction of the images.

Image synthesis component 160 generates composite image 165 based on images 155. Composite image 165 depicts the same structures as images 155 and reduces the appearance of artifacts which might be present in images 155. In some embodiments, composite image 165 is an average of all of images 155. Specifically, the real and imaginary values of each complex pixel of image 165 are averages of the real and imaginary values of the same pixel in images 155. In another example, the real and imaginary values of each complex pixel of image 165 are equal to the sum of the real and imaginary values of the same pixel in images 155. Since each of images 155 may include its own unique CS-related artifacts (albeit reduced from images 130), such averaging or summation reduces the appearance of these artifacts within composite image 165.

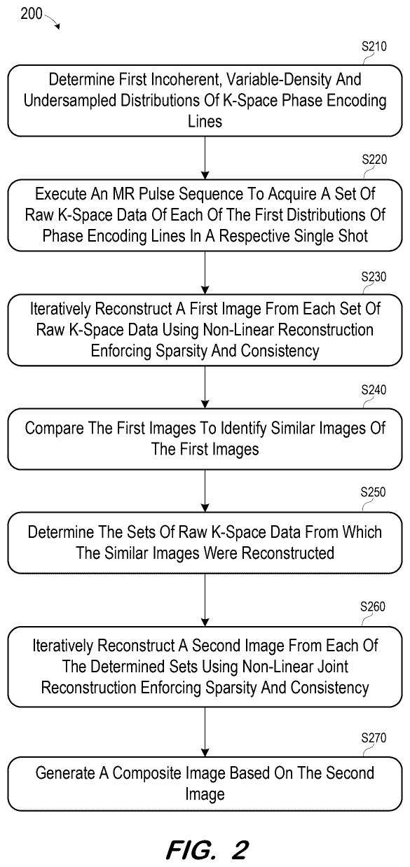

FIG. 2 comprises a flow diagram of process 200 to enhance the sparsity of multiple different incoherent distributions of k-space data and generate an image therefrom according to some embodiments. In some embodiments, various hardware elements of an MR scanner execute program code to perform process 200. The steps of process 200 need not be performed by a single device or system.

Process 200 and all other processes mentioned herein may be embodied in executable program code read from one or more of non-transitory computer-readable media, such as a disk-based or solid-state hard drive, a DVD-ROM, a Flash drive, and a magnetic tape, and then stored in a compressed, uncompiled and/or encrypted format. Such program code may be executed by one or more processing units (e.g., a processor, a processor core, a processor thread) of a computing system to cause the computing system to execute process 200 and/or all other processes mentioned herein. In some embodiments, hard-wired circuitry may be used in place of, or in combination with, program code for implementation of processes according to some embodiments. Embodiments are therefore not limited to any specific combination of hardware and software.

Initially, at S210, a number (e.g., N) of incoherent, variable-density and undersampled distributions of k-space PE lines are determined. Some of the distributions may include one or more identical k-space PE lines, while some distributions may include completely different k-space PE lines. In some embodiments, each distribution may be different from each other distribution (i.e., no distribution includes the same PE lines as another distribution). A distribution may be determined at S210 using any variable-density pseudo-random sampling scheme that is or becomes known.

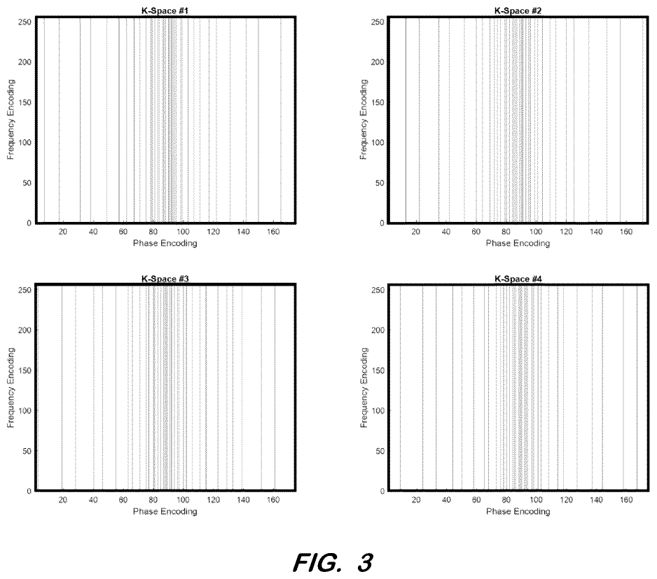

FIG. 3 illustrates four distributions of k-space PE lines according to some embodiments of S210. As shown, each distribution is different from the others, incoherent, variable-density and undersampled. Each distribution is denser at the center of k-space than at the edges, due to the concentration of k-space energy and imaging information of interest at the center. According to the example, each distribution is five-fold undersampled, including 35 of the 175 PE lines of k-space.

According to some embodiments, S210 proceeds by initially calculating the number M of PE lines to be acquired as M=N/R, where N is the number of PE lines in k-space and R is the desired under-sampling rate. M floating point numbers are then generated by the following formula:

Kᵢ=Mod(i*G*N, N)

where i=1, 2, . . . , M, and G=(\sqrt{5}−1)/2~=0.618, i.e., the golden ratio.

A scaling function D(K) is defined, which takes the PE coordinate of a PE line as input and produces a value between a positive minimum value and one. D(K) is defined such that the closer an input PE coordinate is to the center PE line, the closer D(K) is to the positive minimum value, and the closer the PE coordinate is to an edge of k-space, the closer D(K) is to 1.

A new set of M floating point numbers is then generated by the following formula:

K′ᵢ=Kᵢ*D(Kᵢ)

where i=1, 2, . . . , M, and a positive minimum value of D(K) is assigned such that:

|K′ᵢ−K′ⱼ|≥1

for all i, j=1, 2, . . . , M, and i≠j.

Next, a set S of M acquired PE lines on the Cartesian grid is determined by:

Sᵢ=round(K′ᵢ)

where i=1, 2, . . . , M. The set S represents one incoherent, variable-density and undersampled distribution of k-space PE lines.

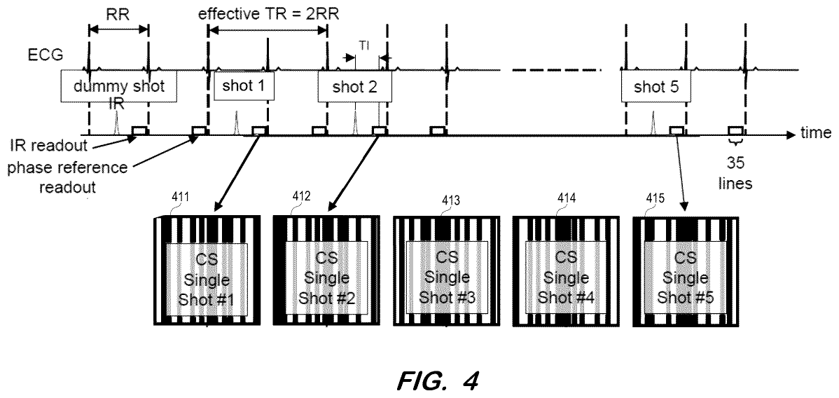

At S220, an MR pulse sequence is executed to acquire, for each distribution, a set of corresponding k-space data (i.e., the k-space data of all lines of the distribution) in a respective single shot. FIG. 4 illustrates a pulse sequence to acquire different sets of k-space data in respective single shots according to some embodiments. The FIG. 4 pulse sequence is a phase-sensitive inversion-recovery (PSIR) pulse sequence in which each of five IR-prepared readouts is followed by acquisition of a corresponding non-IR-prepared phase reference readout. Embodiments are not limited to PSIR or IR pulse sequences. The pulse sequence is triggered based on the patient's ECG signal such that all k-space sets (i.e., IR and phase reference) are acquired during the diastolic phase of the RR-interval.

According to some embodiments, each IR-prepared readout uses a different inversion time. Some embodiments replace the IR-preparation by a combined magnetization transfer and inversion preparation as in the Flow Independent Dark Blood DeLayed Enhancement (FIDDLE) sequence.

Each IR readout acquires the k-space data of a different one of the distributions determined at S210, and its following reference readout acquires the same distribution. Each of distributions 411-415 is a set of M (M=35 in this example) 35 PE lines distributed throughout k-space. According to some embodiments, each of distributions 411-415 is acquired from a same image slice such that the distributions are similar in image space.

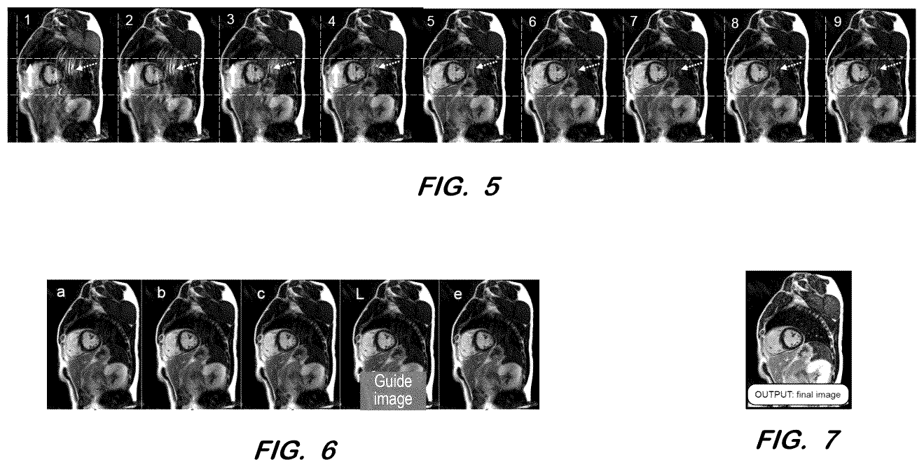

At S230, an image is iteratively reconstructed from each set of k-space data. The reconstruction enforces sparsity and consistency with the k-space data within a given transform domain and may be performed independently for each k-space data set or jointly as described above. Generally, each first image is iteratively reconstructed so as to enforce consistency with its respective set of k-space data and, optionally, joint sparsity of the acquired sets of k-space data in a given transform domain (e.g., the temporal dimension). FIG. 5 illustrates nine images reconstructed at S230 from nine k-space data sets acquired at S220. Each of the nine images corresponds to, i.e., was reconstructed from, a respective one of the nine k-space data sets.

The dotted arrows of the FIG. 5 images indicate artifacts including incomplete removal of ghosting of the bright chest fat signal. The location of the left ventricle relative to the upper horizontal dashed line indicates respiratory motion in images 1 to 4, as marked by the solid upward arrows. Images 5 to 9 depict an end-expiration position in which the heart does not move. Despite this absence of motion, artifacts are also observed in images 5 to 9.

The first images are compared to one another at S240 to identify similar images of the first images. As described above, S240 may consist of determining differences between each of the first images. The comparison at S240 may consider only those pixels of the first images which are located in a predefined region of interest. The identified similar images are a proper subset of the first images. For purposes of example, it will be assumed that images 5 to 9 of FIG. 5 are identified as similar at S240.

Next, at S250, the k-space data sets from which the identified similar images were reconstructed are identified. The k-space data sets acquired at S220 may be maintained in a buffer and retrieved therefrom at S250. A second image is reconstructed for each of the retrieved k-space data sets at S260 using non-linear joint reconstruction enforcing sparsity and consistency. FIG. 6 illustrates five images which were jointly reconstructed at S260 from the k-space data sets corresponding to images 5 to 9 of FIG. 5. The artifacts of images 5 to 9 of FIG. 5 are absent from the images of FIG. 6 due to the enhanced sparsity of their respective k-space data as compared to the joint sparsity of the k-space data sets of images 1 to 9 of FIG. 5.

A brief description of CS reconstruction now follows. Generally, CS reconstruction iterates between image space and a transform space W to determine an image x which minimizes ∥Ax−y∥₂²+λ∥Wx∥₁, in which y denotes the acquired incoherent, variable-density distribution of PE lines and A is the system matrix describing the data acquisition process (i.e., the transform from spatio-temporal to frequency domain). A consists of the coil sensitivity maps of individual receiver coil elements, the Fourier transform, and the distribution of acquired lines. The term ∥Ax−y∥₂² represents the ‘data consistency’ and is the least-squares difference (i.e., the L2 norm, ∥·∥₂²) between the estimated image x and the acquired k-space data y. The term λ∥Wx∥₁ describes the ‘transform sparsity’ and is the sum of the absolute values of the pixels in the transform space (i.e., the L1 norm ∥·∥₁). λ is an empirical weighting factor for balancing data consistency vs. transform sparsity.

Initially, y is Fourier transformed into an image. This image suffers from strong sub-sampling aliasing artifacts which appear ‘noise like’ due to the incoherence of the sub-sampling. As will be described below, these artifacts may be effectively suppressed by the denoising effects of CS reconstruction. The image is transformed into a sparse representation in W-space. The image ‘informational content’ is concentrated within a relatively small region in W-space, while most pixels exhibit low values. This characteristic allows denoising via a thresholding procedure. For example, all pixels with a value < threshold are set to zero, and the threshold is subtracted from all other pixel values. The resulting representation includes more zero pixels (coefficients) and the sparsity of the image in W-space is increased.

The W-space representation is transformed back into image space with the inverse transformation W⁻¹. The image exhibits less noise than the initial image. This corresponds to a suppression of the noise-like aliasing artifacts due to the incoherent sampling.

An inverse Fast Fourier transformation FFT⁻¹ is applied to the denoised image to convert the image to k-space. This k-space is a complete k-space so, in order to compare this k-space to y, the k-space is masked to set PE lines which do not exist in y to 0. A difference k-space is determined by subtracting the masked k-space from the measured k-space y. The difference k-space corresponds to the error (i.e., data inconsistency) created by the above-described thresholding step.

A Fourier transformation converts the difference k-space into a difference image and the difference image is added to the initially-created image. This updated image exhibits less noise-like artifacts (i.e., corresponding to a higher sparsity in W-space) than the initially-created image. The updated image is converted to W-space as described above and the process iterate. Each iteration increases the sparsity (in W-space), which corresponds to reducing the aliasing artifacts in image space. Simultaneously, consistency of the reconstructed image with measured k-space y is maintained. The final image is consistent with measured data measured k-space y and is substantially free of noise-like aliasing artifacts due to the maximization of the transform sparsity.

A composite image is generated from the reconstructed images at S270. For example, the FIG. 6 images may be averaged at S270 to generate the composite image of FIG. 7. Accordingly, the real and imaginary values of each complex pixel of the FIG. 7 composite image are averages of the real and imaginary values of the same pixel in the FIG. 6 images. S270 may serve to “average away” any image-specific CS-related artifacts.

According to some embodiments, S270 comprises determining a guide image of the second images and registering and motion-correcting the second images with respect to the guide image. The guide image may comprise one of the second images, as indicated in FIG. 6, an average image of the second images, or another guide image.

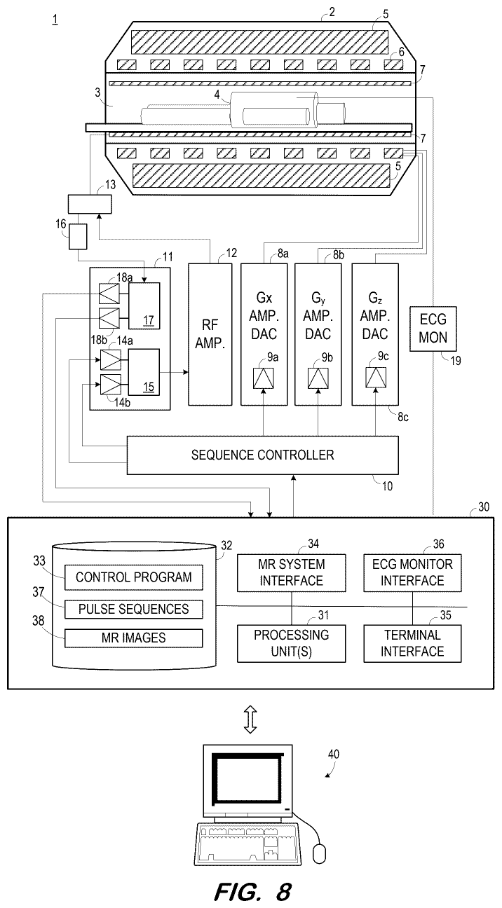

FIG. 8 illustrates MR system 1 according to some embodiments. MR system 1 includes MR chassis 2, which defines bore 3 in which patient 4 is disposed. MR chassis 2 includes polarizing main magnet 5, gradient coils 6 and RF coil 7 arranged about bore 3. According to some embodiments, polarizing main magnet 5 generates a uniform main magnetic field (B₀) and RF coil 7 emits an excitation field (B₁).

According to MR techniques, a substance (e.g., human tissue) is subjected to a main polarizing magnetic field (i.e., B₀), causing the individual magnetic moments of the nuclear spins in the substance to process about the polarizing field in random order at their characteristic Larmor frequency, in an attempt to align with the field. A net magnetic moment M_{z} is produced in the direction of the polarizing field, and the randomly-oriented magnetic components in the perpendicular plane (the x-y plane) cancel out one another.

The substance is then subjected to an excitation field (i.e., B₁) created by emission of a radiofrequency (RF) pulse, which is in the x-y plane and near the Larmor frequency, causing the net aligned magnetic moment M_{z} to rotate into the x-y plane so as to produce a net transverse magnetic moment Mₜ, which is rotating, or spinning, in the x-y plane at the Larmor frequency. The excitation field is terminated, and signals are emitted by the excited spins as they return to their pre-excitation field state. The emitted signals are detected, digitized and processed to reconstruct an image or a spectrum using one of many well-known MR techniques.

Gradient coils 6 produce magnetic field gradients Gₓ, G_{y}, and G_{z} which are used for position-encoding NMR signals. The magnetic field gradients Gₓ, G_{y}, and G_{z} distort the main magnetic field in a predictable way so that the Larmor frequency of nuclei within the main magnetic field varies as a function of position. Accordingly, an excitation field B₁ which is near a particular Larmor frequency will tip the net aligned moment M_{z} of those nuclei located at field positions which correspond to the particular Larmor frequency, and signals will be emitted only by those nuclei after the excitation field B₁ is terminated.

Gradient coils 6 may consist of three windings, for example, each of which is supplied with current by an amplifier 8a-8c in order to generate a linear gradient field in its respective Cartesian direction (i.e., x, y, or z). Each amplifier 8a-8c includes a digital-analog converter 9a-9c which is controlled by a sequence controller 10 to generate desired gradient pulses at prescribed times.

Sequence controller 10 also controls the generation of RF pulses by RF system 11 and RF power amplifier 12. RF system 11 and RF power amplifier 12 are responsive to a scan prescription and direction from sequence controller 10 to produce RF pulses of the desired frequency, phase, and pulse amplitude waveform. The generated RF pulses may be applied to the whole of RF coil 7 or to one or more local coils or coil arrays. RF coil 7 converts the RF pulses emitted by RF power amplifier 12, via multiplexer 13, into a magnetic alternating field in order to excite the nuclei and align the nuclear spins of the object to be examined or the region of the object to be examined. As mentioned above, RF pulses may be emitted in a magnetization preparation step in order to enhance or suppress certain signals.

The RF pulses are represented digitally as complex numbers. Sequence controller 10 supplies these numbers in real and imaginary parts to digital-analog converters 14a-14b in RF system 11 to create corresponding analog pulse sequences. Transmission channel 15 modulates the pulse sequences with a radio-frequency carrier signal having a base frequency corresponding to the resonance frequency of the nuclear spins in the volume to be imaged.

RF coil 7 both emits radio-frequency pulses as described above and scans the alternating field which is produced as a result of processing nuclear spins, i.e., the nuclear spin echo signals. The received signals are received by multiplexer 13, amplified by RF amplifier 16 and demodulated in receiving channel 17 of RF system 11 in a phase-sensitive manner. Analog-digital converters 18a and 18b convert the demodulated signals into digitized real and imaginary components.

Electrocardiograph (“ECG”) monitor 19 acquires ECG signals from electrodes placed on patient 4. Such physiological signals may be used by sequence controller 10 to synchronize, or “gate”, transmitted RF pulses of a pulse sequence based on the heartbeat of patient 4 as described herein.

Computing system 30 receives the digitized real and imaginary components from analog-digital converters 18a and 18b and may process the components according to known techniques. Such processing may, for example, include CS-reconstruction of images from different incoherent undersampled k-space data and combining the images as described herein, performing other image reconstruction techniques, applying filters to raw k-space data or to reconstructed images, generating functional magnetic resonance images, calculating motion or flow images, and generating a chemical shift vs. magnitude spectrum.

System 30 may comprise any general-purpose or dedicated computing system. Accordingly, system 30 includes one or more processing units 31 (e.g., processors, processor cores, execution threads, etc.) configured to execute processor-executable program code to cause system 30 to operate as described herein, and storage device 32 for storing the program code. Storage device 32 may comprise one or more fixed disks, solid-state random-access memory, and/or removable media (e.g., a thumb drive) mounted in a corresponding interface (e.g., a USB port).

One or more processing units 31 may execute program code of control program 33 to provide instructions to sequence controller 10 via MR system interface 34. For example, sequence controller 10 may be instructed to initiate a desired pulse sequence of pulse sequences 37. In particular, sequence controller 10 may be instructed to control the switching of magnetic field gradients via amplifiers 8a-8c at appropriate times, the transmission of radio-frequency pulses having a specified phase and amplitude at specified times via RF system 11 and RF amplifier 12, and the readout of the resulting MR signals. The timing of the various pulses of a pulse sequence may be based on physiological data received by ECG monitor interface 36.

Storage device 32 stores MR images 38 generated as described herein. Such images may be provided to terminal 40 via terminal interface 35 of system 30. Terminal interface 35 may also receive input from terminal 40, which may be used to provide commands to control program 33 in order to acquire k-space sets and generate images as described herein. Terminal 40 may comprise a display device and an input device coupled to system 30. In some embodiments, terminal 40 is a separate computing device such as, but not limited to, a desktop computer, a laptop computer, a tablet computer, and a smartphone.

Each element of system 1 may include other elements which are necessary for the operation thereof, as well as additional elements for providing functions other than those described herein. Storage device 32 may also store data and other program code for providing additional functionality and/or which are necessary for operation of system 30, such as device drivers, operating system files, etc.

Executable program code according to the above description may be stored on a form of non-transitory computer-readable media. Computer-readable media includes volatile and nonvolatile, removable, and non-removable media implemented in any method or technology for storage of information such as program code, data structures, program modules or other data. Computer-readable media includes, but is not limited to, random access memory (RAM), read-only memory (ROM), electrically erasable programmable ROM (EEPROM), flash memory or other memory technology, compact disk ROM (CD-ROM), digital volatile disks (DVD) or other optical storage, magnetic cassettes, magnetic tape, magnetic disk storage or other magnetic storage devices, or any other medium which can be used to store the desired instructions and which may be accessed by a system (e.g., a computer), including by internet or other computer network form of access.

The foregoing diagrams represent logical architectures for describing processes according to some embodiments, and actual implementations may include more, or different components arranged in other manners. Other topologies may be used in conjunction with other embodiments. Moreover, each component or device described herein may be implemented by any number of devices in communication via any number of other public and/or private networks. Two or more of such computing devices may be located remote from one another and may communicate with one another via any known manner of network(s) and/or a dedicated connection. Each component or device may comprise any number of hardware and/or software elements suitable to provide the functions described herein as well as any other functions. For example, any computing device used in an implementation of a system according to some embodiments may include a processor to execute program code such that the computing device operates as described herein.

Embodiments described herein are solely for the purpose of illustration. Those in the art will recognize other embodiments may be practiced with modifications and alterations to that described above.

What is claimed is:

1. A magnetic resonance imaging system comprising:
a magnet system configured to generate a polarizing magnetic field about at least a portion of a subject;
a plurality of gradient coils configured to apply at least one gradient field to the polarizing magnetic field;
a radio frequency (RF) system configured to apply an excitation field to the subject and to acquire magnetic resonance (MR) data from the subject; and
a processing unit to execute program code to cause the system to:
acquire k-space data sets, each of the k-space data sets comprising a different incoherent variable-density under-sampled combination of k-space phase encoding lines;
reconstruct a first image from each of the k-space data sets;
select a plurality of the reconstructed first images based on similarities between the first images;
determine a plurality of k-space data sets from which the selected plurality of the first images were reconstructed, the plurality of k-space data sets being a proper subset of the k-space data sets;
jointly reconstruct a second image from each of the plurality of k-space data sets; and
generate a composite image based on the second images.

2. The system of claim 1, wherein selection of the plurality of the reconstructed first images comprises determination that the selected plurality of the reconstructed first images are similar to one another and that others of the reconstructed first images are not similar to the selected plurality of the reconstructed first images.

3. The system of claim 2, wherein determination that the selected plurality of the reconstructed first images are similar to one another comprises determination that a selected subregion of each the plurality of the reconstructed first images is similar.

4. The system of claim 1, wherein each of the k-space data sets is acquired in a single shot.

5. The system of claim 4, wherein each single shot is preceded by an inversion recovery preparation and a time delay.

6. The system of claim 5, wherein each single shot is preceded by a different time delay.

7. The system of claim 1, wherein reconstruction of the first image from each of the k-space data sets and joint reconstruction of the second image from each of the plurality of k-space data sets comprise iterative compressed sensing reconstructions.

8. The system of claim 1, wherein selection of the plurality of the reconstructed first images comprises determination of a displacement map for each pair of the first images.

9. The system of claim 8, wherein selection of the plurality of the reconstructed first images comprises determination of an average displacement vector length for each displacement map.

10. The system of claim 9, wherein selection of the plurality of the reconstructed first images comprises determination of an average displacement vector length within a same subregion of each displacement map.

11. The system of claim 1, wherein a first joint sparsity of the plurality of k-space data sets is greater than a second joint sparsity of the k-space data sets.

12. A method comprising:
acquiring k-space data sets, each of the k-space data sets comprising a different combination of k-space phase encoding lines;
reconstructing a first image from each of the k-space data sets;
selecting a plurality of the reconstructed first images;
determining a plurality of k-space data sets from which the selected plurality of the first images were reconstructed, the plurality of k-space data sets being a proper subset of the k-space data sets and a first joint sparsity of the plurality of k-space data sets being greater than a second joint sparsity of the k-space data sets;
reconstructing a second image from only the plurality of k-space data sets; and
generating a composite image based on the second images.

13. The method of claim 12, wherein selecting the plurality of the reconstructed first images comprises determining that the selected plurality of the reconstructed first images are similar to one another and that others of the reconstructed first images are not similar to the selected plurality of the reconstructed first images.

14. The method of claim 13, wherein determining that the selected plurality of the reconstructed first images are similar to one another comprises determining that a selected subregion of each the plurality of the reconstructed first images is similar.

15. The method of claim 12, wherein each of the k-space data sets is acquired in a single shot.

16. The method of claim 15, wherein each single shot is preceded by an inversion recovery preparation and a time delay.

17. The method of claim 16, wherein each single shot is preceded by a different time delay.

18. The method of claim 12, wherein reconstructing the first image from each of the k-space data sets comprises iterative compressed sensing reconstructions and reconstructing of the second image from each of the plurality of k-space data sets comprises iterative joint compressed sensing reconstructions.

19. The method of claim 10, wherein selecting the plurality of the reconstructed first images comprises determination of similarities between each of the first images.

20. One or more non-transitory computer-readable media storing program code executable by one or more processing units to cause a computing system to:
acquire k-space data sets, each of the k-space data sets comprising a different incoherent variable-density under-sampled combination of k-space phase encoding lines;
reconstruct a first image from each of the k-space data sets;
select a plurality of the reconstructed first images;
determine a plurality of k-space data sets from which the selected plurality of the first images were reconstructed, the plurality of k-space data sets being a proper subset of the k-space data sets;
jointly reconstruct a second image from each of the plurality of k-space data sets; and
generate a composite image based on the second images, wherein a first joint sparsity of the plurality of k-space data sets is greater than a second joint sparsity of the k-space data sets.
